(19) United States
(12) Patent Application Publication
(10) Pub. No.: US 2026/0096259 A1
(43) Pub. Date: Apr. 2, 2026

(54) LIGHT-EMITTING MODULE AND LIGHT-EMITTING DEVICE

(71) Applicant: GUANGZHOU LUXVISIONS INNOVATION TECHNOLOGY LIMITED, Guangzhou City (CN)

(72) Inventors: Chen-Fu Huang, Guangzhou City (CN); Wei-Han Wu, Guangzhou City (CN)

(73) Assignee: GUANGZHOU LUXVISIONS INNOVATION TECHNOLOGY LIMITED, Guangzhou City (CN)

(21) Appl. No.: 19/174,850

(22) Filed: Apr. 9, 2025

Related U.S. Application Data
(60) Provisional application No. 63/699,810, filed on Sep. 27, 2024.

(30) Foreign Application Priority Data
Dec. 9, 2024 (CN) 202411800874.5

(51) Int. Cl. H10H 20/857; H10H 20/856

(52) U.S. Cl. CPC H10H 20/857; H10H 20/856

(57) ABSTRACT

A light-emitting module and a light-emitting device are provided. The light-emitting module includes a substrate, a conductive pillar, an internal pad, a light-emitting element, and an external pad. The conductive pillar is disposed in a through hole of the substrate and includes first, second, and third portions. The first portion includes a first metal. The second and third portions are respectively connected to two ends of the first portion. The second and third portions include an alloy. The alloy includes a second metal and a third metal different from the first metal. The internal pad is connected to the second portion of the conductive pillar and electrically connected to the light-emitting element. The external pad is connected to the third portion of the conductive pillar. The conductive pillar, having high electron mobility, may reduce resistivity more effectively, thereby improving the performance of the light-emitting device and the light-emitting module thereof.

### CROSS-REFERENCE TO RELATED APPLICATION

This application claims the priority benefit of U.S. provisional application Ser. No. 63/699,810, filed on Sep. 27, 2024 and China application serial no. 202411800874.5, filed on Dec. 9, 2024. The entirety of each of the above-mentioned patent applications is hereby incorporated by reference herein and made a part of this specification.

### BACKGROUND

### Technical Field

The disclosure relates to a light-emitting module and a light-emitting device.

### Description of Related Art

Copper pillar bumps are used in flip-chip packaging to connect a light-emitting chip and a ceramic substrate. Compared with tin-lead bumps, copper pillar bumps have better performance and lower overall packaging cost. However, in current technology, a tin-plated layer is plated on a copper-plated layer, and the process below the copper-plated layer is relatively complex and requires higher cost. In view of this, the bump structure may require improvement.

### SUMMARY

The disclosure provides a light-emitting module having good performance and low cost.

The disclosure provides a light-emitting device having good performance and low cost.

According to an embodiment of the disclosure, a light-emitting module includes a substrate, at least one conductive pillar, an internal pad, a light-emitting element, and an external pad. The substrate has a first surface, a second surface, and at least one through hole. The first surface is relative to the second surface, and the at least one through hole penetrates through the first surface and the second surface. The at least one conductive pillar is disposed in the at least one through hole. Each conductive pillar includes a first portion, a second portion, and a third portion. The first portion includes a first metal. The second portion and the third portion are respectively connected to two ends of the first portion. The second portion and the third portion include an alloy. The alloy includes a second metal and a third metal, and the second metal and the third metal are different from the first metal. The internal pad is disposed on the first surface of the substrate and connected to the second portion of each conductive pillar. The light-emitting element is disposed on the internal pad and electrically connected to the internal pad. The internal pad is located between the light-emitting element and the first surface of the substrate. The external pad is disposed on the second surface of the substrate and connected to the third portion of each conductive pillar.

According to an embodiment of the disclosure, a light-emitting device includes the above light-emitting module and an optical component. The light-emitting element of the light-emitting module is configured to emit an illumination beam, and the optical component is disposed on a transmission path of the illumination beam.

In the light-emitting device and the light-emitting module according to the embodiment of the disclosure, the first metal is a copper, and the second metal and the third metal are a tin-silver alloy.

In the light-emitting device and the light-emitting module according to the embodiment of the disclosure, the light-emitting element includes at least one light-emitting chip and a phosphor layer covering the at least one light-emitting chip.

In the light-emitting device and the light-emitting module according to the embodiment of the disclosure, the light-emitting element further includes an encapsulation layer disposed on the phosphor layer. The phosphor layer is located between the encapsulation layer and the light-emitting chip.

In the light-emitting device and the light-emitting module according to the embodiment of the disclosure, the light-emitting element includes at least one light-emitting chip and a reflective layer disposed around the at least one light-emitting chip.

In the light-emitting device and the light-emitting module according to the embodiment of the disclosure, the light-emitting element includes at least one light-emitting chip. Each light-emitting chip of the at least one light-emitting chip includes a first-type semiconductor layer, a second-type semiconductor layer, an active layer disposed between the first-type semiconductor layer and the second-type semiconductor layer, a first electrode electrically connected to the first-type semiconductor layer, and a second electrode electrically connected to the second-type semiconductor layer. The at least one conductive pillar is multiple conductive pillars. The at least one through hole is multiple through holes. The conductive pillars are respectively disposed in the through holes of the substrate. The conductive pillars are arranged in multiple conductive pillar rows. The internal pad includes a first internal sub-pad and a second internal sub-pad that are structurally separated from each other. The first electrode and the second electrode of each light-emitting chip are respectively electrically connected to the first internal sub-pad and the second internal sub-pad, and the first internal sub-pad and the second internal sub-pad are respectively electrically connected to the conductive pillar rows.

In the light-emitting device and the light-emitting module according to the embodiment of the disclosure, the external pad includes a first external sub-pad and a second external sub-pad that are structurally separated from each other, and the first external sub-pad and the second external sub-pad are respectively electrically connected to the conductive pillar rows.

### BRIEF DESCRIPTION OF THE DRAWINGS

FIG. 1 is a perspective exploded schematic view of a light-emitting module according to an embodiment of the disclosure.

FIG. 2 is a top schematic view of a substrate and a conductive pillar of a light-emitting module according to an embodiment of the disclosure.

FIG. 3 is a bottom schematic view of a substrate and a conductive pillar of a light-emitting module according to an embodiment of the disclosure.

FIG. 4 is a cross-sectional schematic view of a light-emitting module according to an embodiment of the disclosure.

FIG. 5 is an enlarged schematic view of a conductive pillar of a light-emitting module according to an embodiment of the disclosure.

FIG. 6 is a cross-sectional schematic view of a light-emitting element according to an embodiment of the disclosure.

FIG. 7 is a cross-sectional schematic view of a light-emitting chip of a light-emitting element according to an embodiment of the disclosure.

FIG. 8 is a cross-sectional schematic view of a light-emitting device according to an embodiment of the disclosure.

### DESCRIPTION OF THE EMBODIMENTS

Reference will now be made in detail to the exemplary embodiments of the present invention, examples of which are illustrated in the accompanying drawings. Wherever possible, the same reference numbers are used in the drawings and the description to refer to the same or like parts.

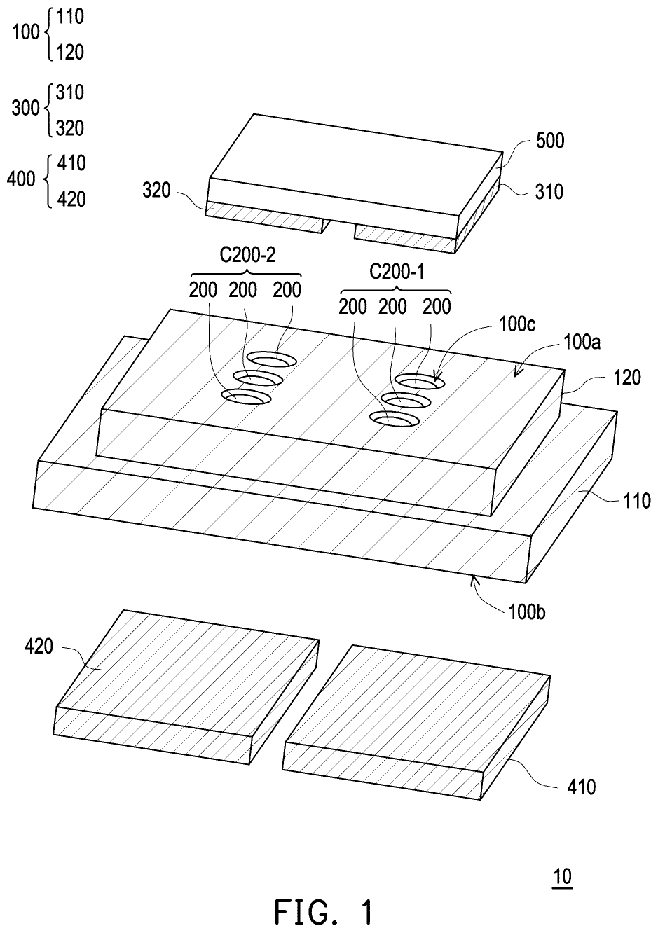

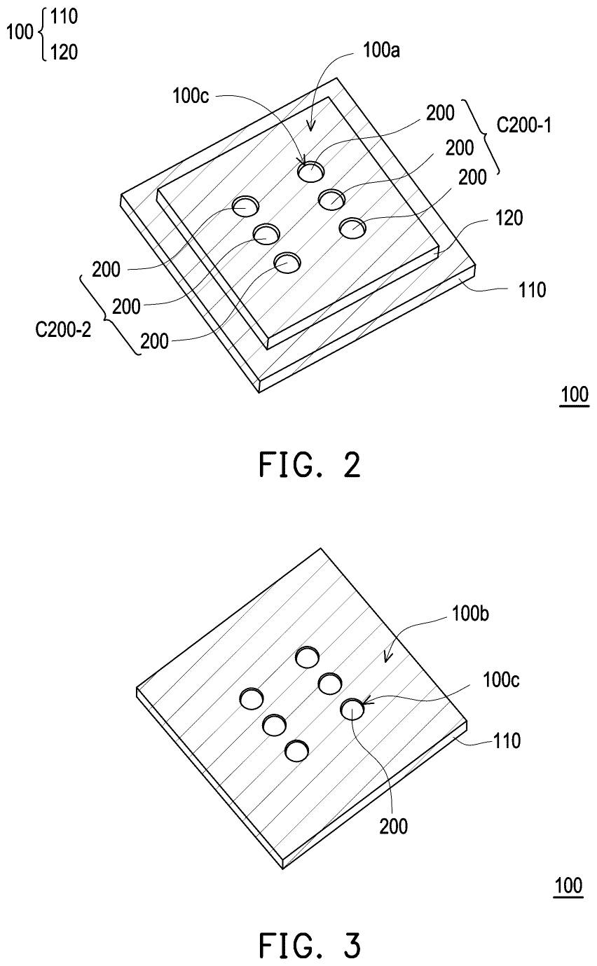

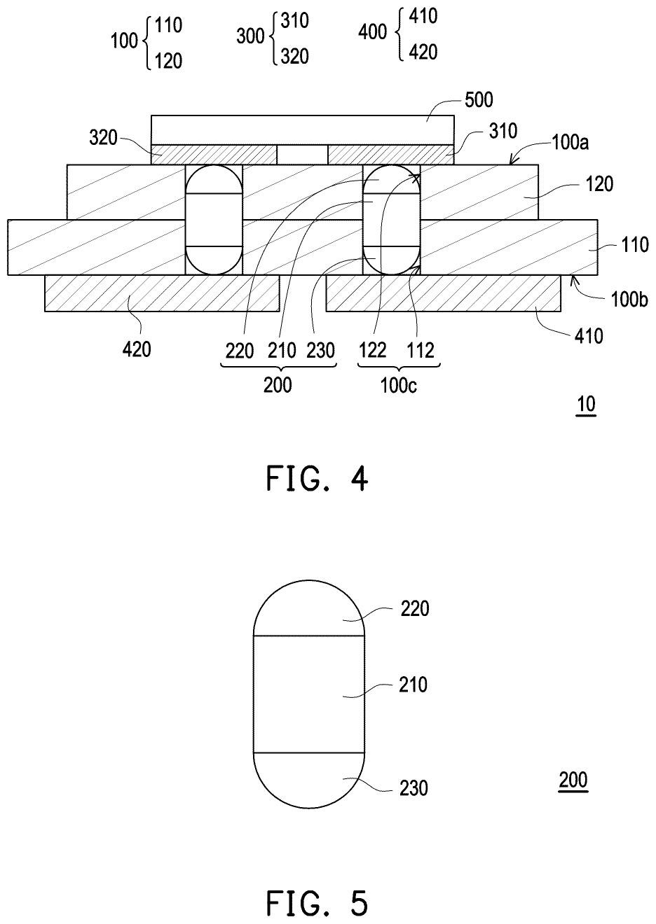

FIG. 1 is a perspective exploded schematic view of a light-emitting module according to an embodiment of the disclosure. FIG. 2 is a top schematic view of a substrate and a conductive pillar of a light-emitting module according to an embodiment of the disclosure. FIG. 3 is a bottom schematic view of a substrate and a conductive pillar of a light-emitting module according to an embodiment of the disclosure. FIG. 4 is a cross-sectional schematic view of a light-emitting module according to an embodiment of the disclosure.

Referring to FIGS. 1, 2, 3, and 4, a light-emitting module 10 includes a substrate 100. The substrate 100 has a first surface 100a, a second surface 100b, and at least one through hole 100c. The first surface 100a is opposite to the second surface 100b. The at least one through hole 100c penetrates through the first surface 100a and the second surface 100b.

In some embodiments, the substrate 100 may have multiple through holes 100c, wherein each through hole 100c penetrates through the first surface 100a and the second surface 100b of the substrate 100. For example, in some embodiments, the substrate 100 may include a first sub-substrate 110 and a second sub-substrate 120, the second sub-substrate 110 is stacked on the first sub-substrate 120, the first sub-substrate 110 has multiple first sub-through holes 112, the second sub-substrate 120 has multiple second sub-through holes 122, and each first sub-through hole 112 communicates with a corresponding one second sub-through hole 122 to form one through hole 100c. In short, in some embodiments, the substrate 100 may optionally be a composite substrate. However, the disclosure is not limited thereto. In other embodiments, the substrate 100 may also be a single-piece substrate. In some embodiments, the material of the substrate 100 is an insulating material. For example, the material of the substrate 100 may be ceramic, but the disclosure is not limited thereto.

The light-emitting module 10 further includes at least one conductive pillar 200, disposed in the at least one through hole 100c of the substrate 100. For example, in some embodiments, the light-emitting module 10 may include multiple conductive pillars 200, respectively disposed in the through holes 100c of the substrate 100. Furthermore, in some embodiments, the conductive pillars 200 may be arranged in multiple conductive pillar rows C200-1 and C200-2, but the disclosure is not limited thereto.

FIG. 5 is an enlarged schematic view of a conductive pillar of a light-emitting module according to an embodiment of the disclosure. Referring to FIGS. 1, 4, and 5, each conductive pillar 200 includes a first portion 210, a second portion 220, and a third portion 230, wherein the second portion 220 and the third portion 230 are respectively connected to two ends of the first portion 210. It is noted that the first portion 210 includes a first metal, the second portion 220 and the third portion 230 include an alloy, the alloy includes a second metal and a third metal, and the second metal and the third metal are different from the first metal. Accordingly, the conductive pillar 200 may have high electron mobility, may reduce resistivity more effectively, and may improve the performance of the light-emitting module 100. For example, in some embodiments, the first metal may be copper (Cu), and the alloy may be tin-silver alloy (SnAg), but the disclosure is not limited thereto.

Referring to FIGS. 1, 4, and 5, the light-emitting module 100 further includes an internal pad 300 and an external pad 400. The internal pad 300 is disposed on the first surface 100a of the substrate 100 and connected to the second portion 220 of each conductive pillar 200. The external pad 400 is disposed on the second surface 100b of the substrate 100 and connected to the third portion 230 of each conductive pillar 200. The substrate 100 is located between the internal pad 300 and the external pad 400. In some embodiments, the internal pad 300 and the external pad 400 are generally in a sheet shape. Contact between the dot-distributed conductive pillars 200 and the internal pad 300 and the external pad 400 may prevent deformation of the sheet-shaped internal pad 300 and external pad 400.

Referring to FIGS. 1, 4, and 5, in some embodiments, the internal pad 300 may include a first internal sub-pad 310 and a second internal sub-pad 320 that are structurally separated from each other. The first internal sub-pad 310 is electrically connected to the conductive pillars 200 of one conductive pillar row C200-1, and the second internal sub-pad 320 is electrically connected to the conductive pillars 200 of another conductive pillar row C200-2. In some embodiments, the external pad 400 may include a first external sub-pad 410 and a second external sub-pad 420 that are structurally separated from each other. The first external sub-pad 410 is electrically connected to the conductive pillars 200 of one conductive pillar row C200-1, and the second external sub-pad 420 is electrically connected to the conductive pillars 200 of another conductive pillar row C200-2.

Referring to FIGS. 1 and 4, the light-emitting module 10 further includes a light-emitting element 500 disposed on the internal pad 300. The internal pad 300 is located between the light-emitting element 500 and the first surface 100a of the substrate 100. The light-emitting element 500 is electrically connected to the internal pad 300. An external power source (not shown) may supply power to the light-emitting element 500 through the external pad 400, the conductive pillars 200, and the internal pad 300.

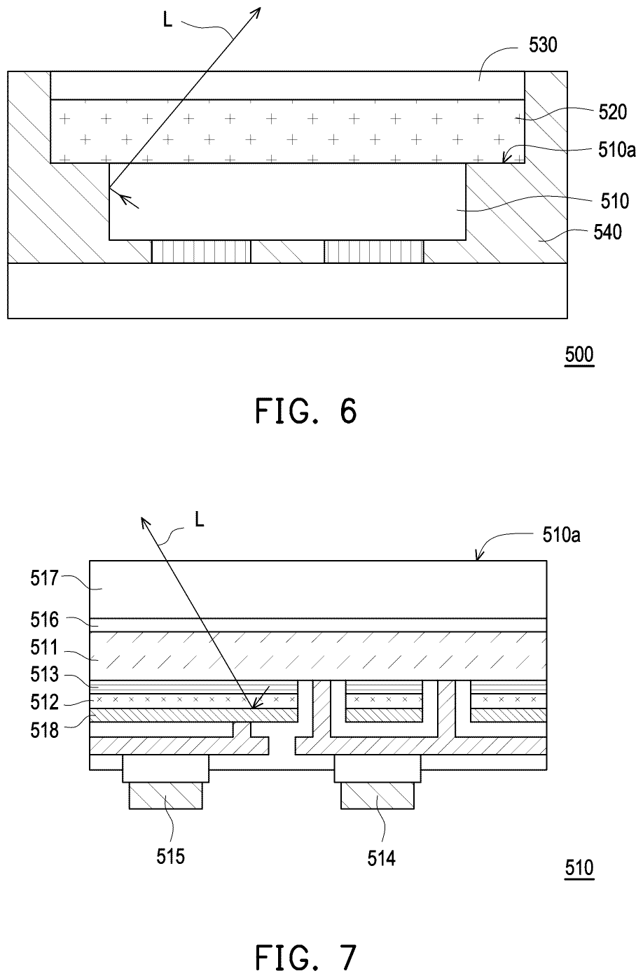

FIG. 6 is a cross-sectional schematic view of a light-emitting element according to an embodiment of the disclosure. FIG. 7 is a cross-sectional schematic view of a light-emitting chip of a light-emitting element according to an embodiment of the disclosure. Referring to FIGS. 4, 6, and 7, the light-emitting element 500 includes at least one light-emitting chip 510. Each light-emitting chip 510 includes a first-type semiconductor layer 511, a second-type semiconductor layer 512, an active layer 513 disposed between the first-type semiconductor layer 511 and the second-type semiconductor layer 512, a first electrode 514 electrically connected to the first-type semiconductor layer 511, and a second electrode 515 electrically connected to the second-type semiconductor layer 512. The first electrode 514 and the second electrode 515 of the light-emitting chip 500 are respectively electrically connected to the first internal sub-pad 310 and the second internal sub-pad 320. In some embodiments, the first-type semiconductor layer 511 may be an N-type semiconductor layer (e.g., N-GaN), the second-type semiconductor layer 512 may be a P-type semiconductor layer (e.g., P-GaN), and the active layer 513 may be a multiple quantum well structure, but the disclosure is not limited thereto. In some embodiments, the light-emitting chip 510 may optionally include a buffer layer 516, a growth substrate 517, and a reflector 518. The buffer layer 516 is disposed between the growth substrate 517 and the first-type semiconductor layer 511. The growth substrate 517 may optionally have multiple optical microstructures (not shown) to improve the light extraction efficiency of the light-emitting chip 510. The active layer 513 may be disposed between the reflector 518 and a light-emitting surface 510a of the light-emitting chip 510, so as to reflect an illumination beam L emitted from the active layer 513 toward the light-emitting surface 510a of the light-emitting chip 510.

Referring to FIG. 6, in some embodiments, the light-emitting element 500, in addition to including the light-emitting chip 510, may optionally include a phosphor layer 520. The phosphor layer 520 covers a light-emitting surface 510a of the light-emitting chip 510. In some embodiments, the light-emitting element 500 may optionally include an encapsulation layer 530, disposed on the phosphor layer 520. The phosphor layer 520 is located between the encapsulation layer 530 and the light-emitting chip 510. In some embodiments, the material of the encapsulation layer 530 is, for example, silicone, but the disclosure is not limited thereto. In some embodiments, the light-emitting element 500 may optionally include a reflective layer 540, disposed around the light-emitting chip 510, to guide an illumination beam that is not directed to the above of the light-emitting surface 510a to be emitted from the above of the light-emitting surface 510a.

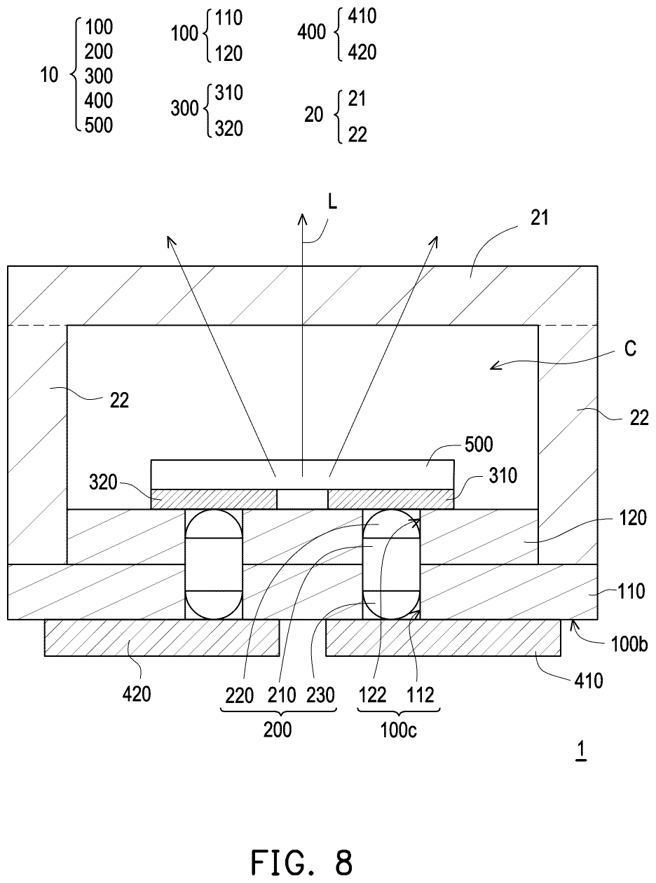

FIG. 8 is a cross-sectional schematic view of a light-emitting device according to an embodiment of the disclosure. Referring to FIGS. 4 and 8, a light-emitting device 1 includes the above light-emitting module 10 and an optical component 20. The light-emitting element 500 of the light-emitting module 10 is configured to emit the illumination beam L, and the optical component 20 is disposed on a transmission path of the illumination beam L. For example, in some embodiments, the optical component 20 may include a three-dimensional quartz lens for adjusting a light pattern of the illumination beam L, but the disclosure is not limited thereto. In some embodiments, the light-emitting element 500 of the light-emitting module 10 may be disposed in a cavity C surrounded by the optical component 20 and the light-emitting module 10. In some embodiments, an area of the first sub-substrate 110 of the light-emitting module 10 may be greater than an area of the second sub-substrate 120 of the light-emitting module 10. The second sub-substrate 120 with a smaller area is stacked on the first sub-substrate 110 with a larger area to form a stepped structure 100s. The optical component 20 may include a main portion 21 disposed right above the light-emitting module 10 and a support portion 22 connected to a periphery of the main portion 21 and extending toward a substrate 100 of the light-emitting module 10, wherein the support portion 22 of the optical component 20 may be disposed on the stepped structure 100s of the substrate 100 to surround the cavity C together with the substrate 100, but the disclosure is not limited thereto.

Finally, it should be noted that the above embodiments are only configured to illustrate the technical solutions of the disclosure and are not intended to limit the disclosure. Although the disclosure has been described in detail with reference to the foregoing embodiments, those skilled in the art should understand that modifications may still be made to the technical solutions described in the foregoing embodiments, or some or all of the technical features may be replaced with equivalents. These modifications or replacements do not cause the essence of the corresponding technical solutions to deviate from the scope of the technical solutions in the embodiments of the disclosure.

What is claimed is:

1. A light-emitting module, comprising:
a substrate, having a first surface, a second surface, and at least one through hole, wherein the first surface is relative to the second surface, and the at least one through hole penetrates through the first surface and the second surface;
at least one conductive pillar, disposed in the at least one through hole, wherein each conductive pillar of the at least one conductive pillar comprises:
a first portion, comprising a first metal; and
a second portion and a third portion, respectively connected to two ends of the first portion, wherein the second portion and the third portion comprise an alloy, the alloy comprises a second metal and a third metal, and the second metal and the third metal are different from the first metal;
an internal pad, disposed on the first surface of the substrate and connected to the second portion of the each conductive pillar;
a light-emitting element, disposed on the internal pad and electrically connected to the internal pad, wherein the internal pad is located between the light-emitting element and the first surface of the substrate; and
an external pad, disposed on the second surface of the substrate and connected to the third portion of the each conductive pillar.

2. The light-emitting module according to claim 1, wherein the first metal is a copper, and the second metal and the third metal are a tin-silver alloy.

3. The light-emitting module according to claim 1, wherein the light-emitting element comprises at least one light-emitting chip and a phosphor layer covering the at least one light-emitting chip.

4. The light-emitting module according to claim 3, wherein the light-emitting element further comprises:
an encapsulation layer, disposed on the phosphor layer, wherein the phosphor layer is located between the encapsulation layer and the at least one light-emitting chip.

5. The light-emitting module according to claim 1, wherein the light-emitting element comprises at least one light-emitting chip and a reflective layer disposed around the at least one light-emitting chip.

6. The light-emitting module according to claim 1, wherein the light-emitting element comprises at least one light-emitting chip, each light-emitting chip of the at least one light-emitting chip comprises a first-type semiconductor layer, a second-type semiconductor layer, an active layer disposed between the first-type semiconductor layer and the second-type semiconductor layer, a first electrode electrically connected to the first-type semiconductor layer, and a second electrode electrically connected to the second-type semiconductor layer, the at least one conductive pillar is a plurality of conductive pillars, the at least one through hole is a plurality of through holes, the plurality of conductive pillars are respectively disposed in the plurality of through holes of the substrate, the plurality of conductive pillars are arranged in a plurality of conductive pillar rows, the internal pad comprises a first internal sub-pad and a second internal sub-pad that are structurally separated from each other, the first electrode and the second electrode of the each light-emitting chip are respectively electrically connected to the first internal sub-pad and the second internal sub-pad, and the first internal sub-pad and the second internal sub-pad are respectively electrically connected to the plurality of conductive pillar rows.

7. The light-emitting module according to claim 6, wherein the external pad comprises a first external sub-pad and a second external sub-pad that are structurally separated from each other, and the first external sub-pad and the second external sub-pad are respectively electrically connected to the plurality of conductive pillar rows.

8. A light-emitting device, comprising:
a light-emitting module, comprising:
a substrate, having a first surface, a second surface, and at least one through hole, wherein the first surface is relative to the second surface, and the at least one through hole penetrates through the first surface and the second surface;
at least one conductive pillar, disposed in the at least one through hole, wherein each conductive pillar of the at least one conductive pillar comprises:
a first portion, comprising a first metal; and
a second portion and a third portion, respectively connected to two ends of the first portion, wherein the second portion and the third portion comprise an alloy, the alloy comprises a second metal and a third metal, and the second metal and the third metal are different from the first metal;
an internal pad, disposed on the first surface of the substrate and connected to the second portion of the each conductive pillar;
a light-emitting element, disposed on the internal pad and electrically connected to the internal pad, wherein the internal pad is located between the light-emitting element and the first surface of the substrate; and
an external pad, disposed on the second surface of the substrate and connected to the third portion of the each conductive pillar; and
an optical component, wherein the light-emitting element of the light-emitting module is configured to emit an illumination beam, and the optical component is disposed on a transmission path of the illumination beam.

9. The light-emitting device according to claim 8, wherein the first metal is a copper, and the second metal and the third metal are a tin and a silver.

10. The light-emitting device according to claim 8, wherein the light-emitting element comprises at least one light-emitting chip and a phosphor layer covering the at least one light-emitting chip.

11. The light-emitting device according to claim 10, wherein the light-emitting element further comprises:
an encapsulation layer, disposed on the phosphor layer, wherein the phosphor layer is located between the encapsulation layer and the at least one light-emitting chip.

12. The light-emitting device according to claim 8, wherein the light-emitting element comprises at least one light-emitting chip and a reflective layer disposed around the at least one light-emitting chip.

13. The light-emitting device according to claim 8, wherein the light-emitting element comprises at least one light-emitting chip, each light-emitting chip of the at least one light-emitting chip comprises a first-type semiconductor layer, a second-type semiconductor layer, an active layer disposed between the first-type semiconductor layer and the second-type semiconductor layer, a first electrode electrically connected to the first-type semiconductor layer, and a second electrode electrically connected to the second-type semiconductor layer, the at least one conductive pillar is a plurality of conductive pillars, the at least one through hole is a plurality of through holes, the plurality of conductive pillars are respectively disposed in the plurality of through holes of the substrate, the plurality of conductive pillars are arranged in a plurality of conductive pillar rows, the internal pad comprises a first internal sub-pad and a second internal sub-pad that are structurally separated from each other, the first electrode and the second electrode of the each light-emitting chip are respectively electrically connected to the first internal sub-pad and the second internal sub-pad, and the first internal sub-pad and the second internal sub-pad are respectively electrically connected to the plurality of conductive pillar rows.

14. The light-emitting device according to claim 13, wherein the external pad comprises a first external sub-pad and a second external sub-pad that are structurally separated from each other, and the first external sub-pad and the second external sub-pad are respectively electrically connected to the plurality of conductive pillar rows.
